(19) United States
(12) Patent Application Publication
(10) Pub. No.: US 2012/0268700 A1
(43) Pub. Date: Oct. 25, 2012

(54) COLOR FILTER SUBSTRATE, FABRICATING METHOD THEREOF AND LCD WITH THE SAME

(75) Inventors: Shi SHU, Beijing (CN); Jinbo LU, Beijing (CN); Jianshe XUE, Beijing (CN); Jisheng ZHAO, Beijing (CN); Lin LI, Beijing (CN)

(73) Assignee: BOE TECHNOLOGY GROUP CO., LTD., Beijing (CN)

(21) Appl. No.: 13/450,830

(22) Filed: Apr. 19, 2012

(30) Foreign Application Priority Data
Apr. 19, 2011 (CN) 201110098346.6

(51) Int. Cl. G02F 1/1335; G03F 7/20; G02B 5/22

(52) U.S. Cl. 349/106; 359/891; 349/110; 430/7

(57) ABSTRACT

The disclosure provides a color filter substrate, a fabricating method of the color filter substrate and a liquid crystal display with the color filter substrate. The color filter substrate comprises a substrate and a barrier wall black matrix layer on the base substrate. The barrier wall black matrix layer defines subpixel regions. The barrier wall black matrix layer comprises a light blocking layer and a barrier wall layer on the light blocking layer.

### BACKGROUND

The present disclosure relates to a liquid crystal display (LCD), and in particular to a color filter substrate, a fabricating method of the color filter substrate, and an LCD comprising the color filter substrate.

A liquid crystal display (LCD) is a non-active emitting device in which a light source is provided by a backlight unit. The backlight unit cooperates with a driving integrated circuit (IC) and a liquid crystal control means to form a grey scale display with black and white colors, which is then rendered into a color display through three color layers of red (R), green (G) and blue (B) color filters (CFs). As such, the color filter substrate is a critical component for colorful display of the liquid crystal display.

In order to achieve a high resolution, a high color contrast and avoid light leakage between respective adjacent subpixels with different colors such as red, green and blue, a black matrix (BM) is utilized to separate red, green and blue color layers in those subpixels. A conventional pigment dispersion method is used to fabricate the black matrix. During this process, if the black matrix is too thick, the thickness would cause incomplete exposure of the black matrix. Moreover, the surface flatness of the black matrix made of a conventional carbon black resin would decrease after development, such that inks for forming the color layers may easily wet the surface of the black matrix when the inks are sprayed or dropped onto the black matrix during fabrication of the color filter substrate, which adversely affects the fabrication of the color filter substrate. Therefore, the thickness of black matrix is required to be relatively thin. However, a thin black matrix may easily cause color mixing of inks with different colors in adjacent color layers upon fabrication of the color filter substrate.

### SUMMARY

The disclosure provides a color filter substrate, a fabricating method of the color filter substrate, and a liquid crystal display. According to the present disclosure, adjacent color inks with different colors would not mix in fabricating the color filter substrate.

According to one aspect of the disclosure, a color filter substrate is provided. The color filter substrate comprises a base substrate and a barrier wall black matrix layer on the base substrate. The barrier wall black matrix layer defines subpixel regions. The barrier wall black matrix layer comprises a light blocking layer and a barrier wall layer on the light blocking layer.

According to embodiments of the disclosure, the color filter substrate may further comprise color layers in the subpixel regions. The barrier wall black matrix layer may be formed of a positive photoresist containing black pigment. The barrier wall layer may have a cross-sectional shape selected from the group consisting of trapezium, rectangle and triangle. The barrier wall layer may not extend beyond the light blocking layer. The barrier wall layer may have a width smaller than a width of the light blocking layer. In one embodiment, the barrier wall layer can be continuous to form grids. Alternatively, the barrier wall layer can comprise a plurality of separate portions each located between adjacent subpixel regions. The barrier wall black matrix layer can be formed by a single exposure process.

According to another aspect of the disclosure, a fabricating method of a color filter substrate is provided. The method comprises steps of: providing a base substrate; providing a layer of black matrix material on the substrate; and exposing the layer of black matrix material to form a barrier wall black matrix layer defining subpixel regions. The barrier wall black matrix layer comprises a light blocking layer and a barrier wall layer on the light blocking layer.

According to embodiments of the disclosure, the black matrix material may be a positive photoresist containing black pigment. The step of said exposing the layer of black matrix material may comprise steps of: exposing the photoresist using a half tone mask such that the exposed photoresist comprises completely exposed regions, unexposed regions and partially exposed regions; and removing the exposed photoresist by a developing process to form a barrier wall layer corresponding to the unexposed regions, a light blocking layer corresponding to the completely exposed regions, and the subpixel regions corresponding to the completely exposed regions. The method may further comprise a step of dispensing color inks into the subpixel regions by an ink jet method to form a plurality of color layers. Before said step of dispensing the color inks into the subpixel region, the method may further comprise thinning the barrier wall layer and the light blocking layer to a predetermined thickness by an aching process.

According to another aspect of the disclosure, a liquid crystal display is provided. The liquid crystal display comprises a color filter substrate. The color filter substrate comprises a base substrate and a barrier wall black matrix layer on the base substrate. The barrier wall black matrix layer defines subpixel regions. The barrier wall black matrix layer comprises a light blocking layer and a barrier wall layer on the light blocking layer.

The embodiments of the disclosure can at least have following benefits. The color filter substrate comprises the barrier wall black matrix layer which comprises the light blocking layer and the barrier wall layer on the light blocking layer. Therefore, the color inks with different colors to be filled in adjacent subpixel regions would not be mixed due to the presence of the barrier wall layer between subpixel regions.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a top view of one embodiment of a barrier wall black matrix layer of a color filter substrate according to the disclosure;

FIG. 2 is a top view of another embodiment of a barrier wall black matrix layer of color filter substrate according to the disclosure;

FIG. 3 is a cross-sectional schematic view of the barrier wall black matrix layer of color filter substrate taken along line a-a′ shown in FIG. 1 or FIG. 2;

FIG. 4 is a cross-sectional schematic view of the barrier wall black matrix layer of color filter substrate taken along line b-b′ shown in FIG. 1 or FIG. 2;

FIG. 5 is a schematic flowchart of a fabricating method of the color filter substrate taken according to one embodiment of the disclosure;

FIG. 6(a) is a schematic view of a substrate in a fabricating method of a color filter substrate according to the present disclosure;

FIG. 6(b) is a schematic view of a providing a photoresist on a substrate in a fabricating method of a color filter substrate according to the present disclosure;

FIG. 6(c) is a schematic view of exposure in a fabricating method of a color filter substrate according to the present disclosure;

FIG. 6(d) is a schematic view after exposure in a fabricating method of a color filter substrate according to the present disclosure;

FIG. 6(e) is a schematic view after development in a fabricating method of a color filter substrate using the present disclosure; and

FIG. 6(f) is a schematic view of color filter substrate fabricated with a fabricating method of a color filter substrate according to the disclosure.

### DETAILED DESCRIPTION

The detailed description will be made in conjunction with the drawings and the exemplary embodiments.

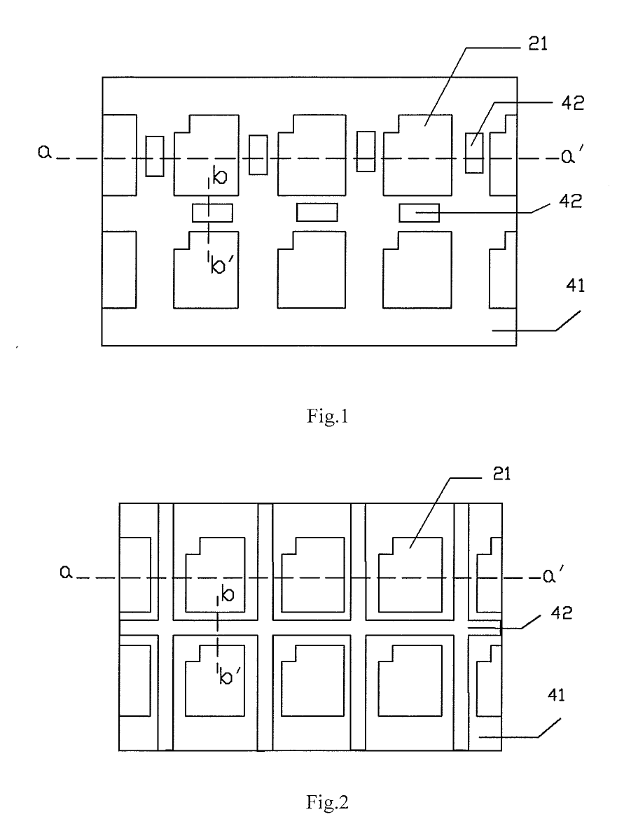

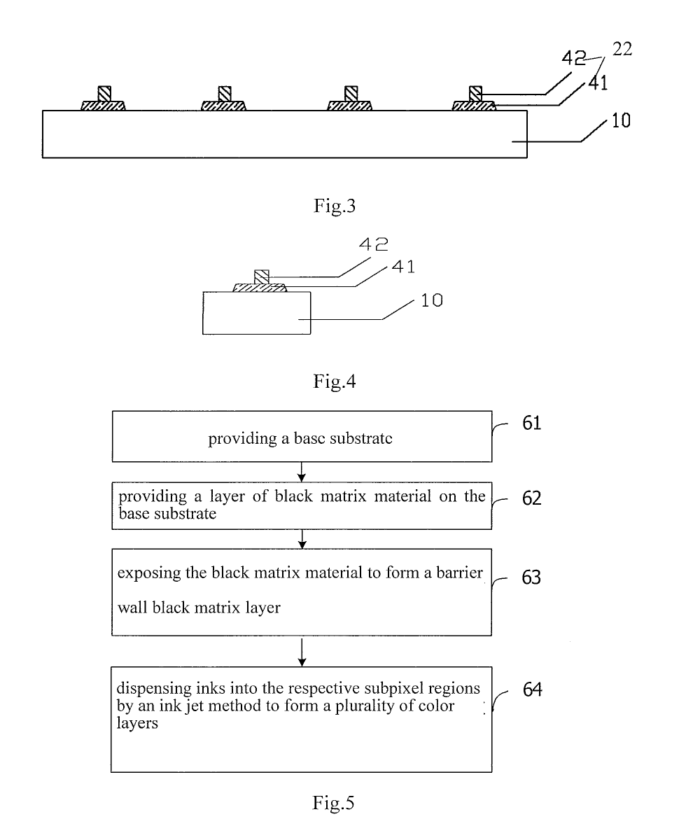

FIG. 1 is a top view of one embodiment of a barrier wall black matrix layer of a color filter substrate described in the disclosure. FIG. 2 is a top view of another embodiment of a barrier wall black matrix layer of a color filter substrate described in the disclosure. FIG. 3 is a cross-sectional schematic view of barrier wall black matrix layer taken along line a-a′ as shown in FIG. 1 or FIG. 2. FIG. 4 is a cross-sectional schematic view of barrier wall black matrix layer taken along line b-b′ as shown in FIG. 1 or FIG. 2. The color filter substrate of the embodiments of the disclosure will be described below in conjunction with FIG. 1, FIG. 2, FIG. 3 and FIG. 4.

As shown in FIG. 1, a color filter substrate in the disclosure comprises a base substrate 10 and a barrier wall black matrix layer 22 on the base substrate 10 for defining subpixel regions 21. The color filter substrate can further comprise color layers in respective subpixel regions 21. The base substrate 10 may be a glass substrate, a silica substrate or a plastic substrate.

The barrier wall black matrix layer 22 comprises a light blocking layer 41 and a barrier wall layer 42 on the light blocking layer 41. The barrier wall layer 42 is composed of a plurality of separate portions each located between adjacent subpixel regions 21. Optionally, the barrier wall black matrix layer is formed of a positive photoresist containing black pigment.

As shown in FIG. 3 and FIG. 4, each portion of the barrier wall layer 42 does not extend beyond the light blocking layer 41 disposed therebelow in other directions. Optionally, each portion of the light blocking layer 41 and the barrier wall layer 42 thereon form a step-like structure. That is to say, each portion of the barrier wall layer 42 has a width smaller than that of the light blocking layer 41 therebelow. Optionally, each portion of the barrier wall layer 42 has a cross-sectional shape selected from trapezium, rectangle or triangle. It should be understood that the cross-sectional shape of each portion of the barrier wall layer 42 is not limited to those shapes in the disclosure as long as it can works as desired.

The color layers can be formed of color inks filled or dropped in the respectively subpixel regions 21 by an ink jet method, for example. The color layers may have different color combinations. For example, the color layers can comprise a red color layer, a blue color layer and a green color layer. In the above configuration, the barrier wall black matrix layer 22 has the barrier wall layer 42 for separating color layers in adjacent subpixels, which prevents color mixing of inks with different colors during such ink jet process. The barrier wall layer 42 does not extend beyond the light blocking layer 41, thus preventing light leakage which is otherwise caused by separation between the color layer and the black matrix due to the volume shrinkage of the color layer after baking and avoiding contrast decrease in the liquid crystal display comprising the color filter substrate.

The barrier wall black matrix layer 22 can be formed of a positive photoresist containing black pigment. That is to say, the positive photoresist containing black pigment is used as the material of the barrier wall black matrix. The black pigment can enhance high optical density of the black matrix and decrease the reflectivity of the black matrix so as to achieve a high contrast. A positive photoresist is used in the present disclosure, which enables a patterning method with a half tone mask or a grey tone mask. After exposure with the half tone mask or the grey tone mask, the exposed positive photoresist forms an unexposed region, a partially exposed region and a completely exposed region. After a developing process, the photoresist in the unexposed region is not developed and retained, the photoresist in the partially exposed region is developed by about 35%-45%, and the photoresist in the completely exposed region is developed and removed completely, so as to form a barrier wall layer, a light blocking layer and subpixel regions accordingly. The present disclosure uses a positive photoresist containing black pigment as the material of the black matrix, therefore the black matrix can be formed by a single exposure process. This can reduce process steps and improve reliability compared with a conventional black matrix material.

FIG. 2 shows another embodiment of the barrier wall black matrix layer of color filter substrate in the disclosure. The embodiment shown in FIG. 2 is substantially the same as the embodiment shown in FIG. 1 and differs in that the barrier wall layer 42 is continuous to form grids which separate the respective subpixel regions 21 in the embodiment shown in FIG. 2. The other aspects of the embodiment shown in FIG. 2 are omitted to avoid redundancy.

FIG. 5 shows a flowchart of a fabricating method of a color filter substrate in the disclosure. The method comprises a step 61 of providing a base substrate; a step 62 of providing a layer of black matrix material on the base substrate; and a step 63 of exposing the black matrix material to form a barrier wall black matrix layer.

Optionally, the black matrix material is a positive photoresist containing black pigment. Accordingly, the step 63 comprises exposing the black matrix material with a half tone mask or a grey tone mask such that the exposed photoresist comprises a completely exposed region, an unexposed region and a partially exposed region. The exposed photoresist is then developed and removed to form a barrier wall layer, a light blocking layer and subpixel regions. The barrier wall layer corresponds to the unexposed region, the light blocking layer corresponds to the partially exposed region, and the subpixel regions correspond to the completely exposed region.

Optionally, the method further comprises a step 64 of dispensing inks into the respective subpixel regions by an ink jet method to form a plurality of color layers.

Optionally, in another embodiment, before the step of dispensing inks into the subpixel regions, the method can further comprise a step of thinning the barrier wall layer and the light blocking layer to a predetermined thickness by an ashing process.

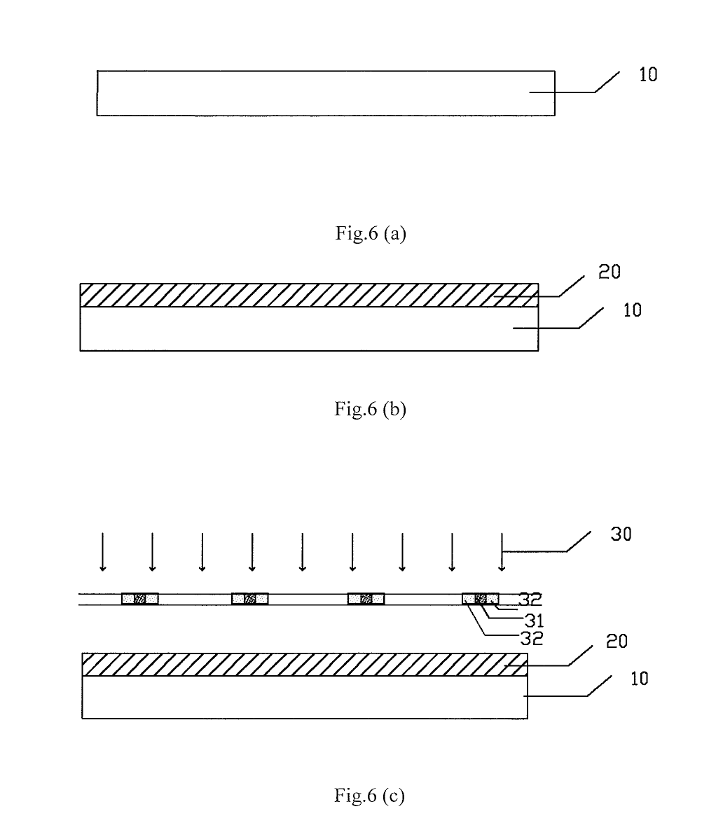

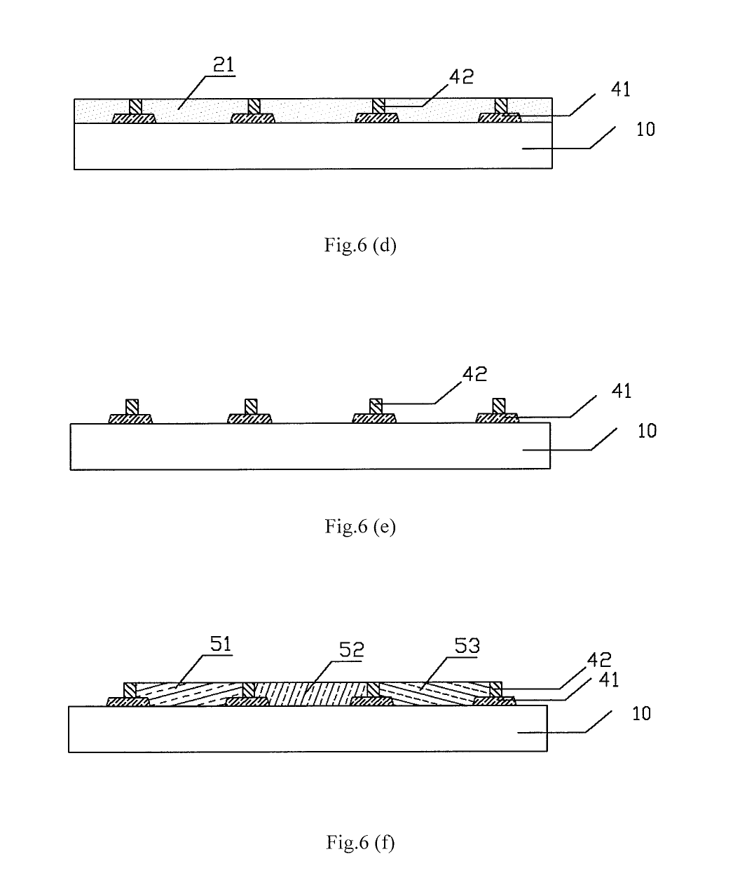

FIG. 6(a) is a schematic view of a substrate in the fabricating method of a color filter substrate according to the present disclosure. FIG. 6(b) is a schematic view of providing photoresist on the substrate in the fabricating method of a color filter substrate according to the present disclosure. FIG. 6(c) is a schematic view of exposure in the fabricating method of a color filter substrate according to the present disclosure. FIG. 6(d) is a schematic view after exposure in a fabricating method of a color filter substrate according to the present disclosure. FIG. 6(e) is a schematic view after development in a fabricating method of a color filter substrate according to the present disclosure. FIG. 6(f) is a schematic view of color filter substrate manufactured using the fabricating method of a color filter substrate according to the disclosure.

The fabricating method of a color filter substrate according to the disclosure will be further described below with reference to FIG. 6(a) to FIG. 6(f).

First, as shown in FIG. 6(a), a base substrate 10 is provided;

Then, as shown in FIG. 6(b), a layer of positive photoresist 20 containing black pigment is applied on the base substrate 10 by a method such as spin coating or a knife coating.

Next, as shown in FIGS. 6(c) and 6(d), the layer of the photoresist 20 is exposed with a half tone mask using UV light 30. In particular, the half tone mask comprises a transmissive region, an opaque region 31 and a half tone region 32 (i.e., a semi-transmissive film) so that the exposed photoresist includes a completely exposed region, an unexposed region corresponding to a barrier wall layer region 42, and a partially exposed region corresponding to a light blocking layer region 41 other than a barrier wall layer. As shown in FIG. 6(c), in the mask, the half tone region 32 is provided around the opaque region 31 such that the barrier wall layer 42 does not extend beyond the light blocking layer 41 after exposure. Optionally, the light blocking layer 41 and the barrier wall layer 42 together form a step structure. That is to say, as shown in FIG. 6(c), the barrier wall layer 42 has a width smaller than the width of the light blocking layer 41. Optionally, in the mask, the grey level profile of the half tone region is preset such that the barrier wall layer 42 has a cross-sectional shape selected from trapezium, rectangle or triangle. For example, the grey level profile of the half tone region may be gradually changed. Accordingly, the cross section shape of the barrier wall layer is in a trapezium or triangle shape. It should be understood that the cross-sectional shape of the barrier wall layer is not limited to those mentioned above in the disclosure, and other shapes can be also adopted as long as the barrier wall layer 42 does not extend beyond the light blocking layer 41. As shown in FIG. 6(d), the exposed photoresist defines the subpixel regions 21.

Then, as shown in FIG. 6(e), the exposed photoresist is developed by removing the completely exposed photoresist in the subpixel regions, leaving the barrier wall black matrix layer 22 comprising the light blocking layer 41 and the barrier wall layer 42 on the light blocking layer 41.

Optionally, the barrier wall black matrix layer 22 can be subject to an ashing process so that the barrier wall black matrix layer 22 can be thinned to an appropriate thickness.

Then, as shown in FIG. 6(f), color inks with different colors can be sprayed or dropped into the respective subpixel regions 21 for example by an ink jet method, and then solidified to form a plurality of color layer. For example as shown in FIG. 6(f), the color layers may include a red layer 51, a blue layer 52 and a green layer 53.

In addition, on the color layers a common electrode layer may be formed in an example. In further another example, a polarizer plate can be attached to the opposite site of the base substrate 10.

In the fabricating method of a color filter substrate according to the present disclosure a half tone mask is used to make the barrier wall black matrix layer, which allow to make a double layer structure consisting of the conventional black matrix layer and the barrier wall with an ink jet method, thus improving productivity and reducing cost due to process simplicity of fabricating color filter substrate with ink jet process.

Furthermore, the barrier wall black matrix layer is fabricated by a single patterning process with a half tone mask. That is to say, by an exposure process of the photoresist containing black pigment with the half tone mask, it is required only one patterning process to obtain the barrier wall black matrix layer. The barrier wall black matrix layer comprises a lower light blocking layer and an upper barrier wall layer on the light blocking layer. Such configuration allows to reliably separate adjacent subpixels, thus avoiding the color mixing of the color inks with different colors upon dispensing the inks. This in turn can improve yield and productivity.

Another embodiment of the present disclosure provides a liquid crystal display with the color filter substrate discussed above. The color filter substrate is assembled with an array substrate to form a display panel.

The present disclosure has the following benefits:

1. In the disclosure, a color filter substrate comprises a barrier wall black matrix layer which comprises a light blocking layer and a barrier wall layer on the light blocking layer. Therefore, the color inks in adjacent subpixels would not be mixed due to the barrier wall layer.

2. Conventionally, the material of black matrix is formed of a resin, chromium oxide or the like. In contrast, the present disclosure uses a photoresist containing black pigment to manufacture black matrix. The black pigment can enhance the high optical density of the black matrix and decrease the reflectivity of the black matrix so as to achieve a high contrast. Therefore, the number of raw materials can be reduced by using the photoresist , which in turn can reduce cost and simplify the process.

3. In the present disclosure, the barrier wall black matrix layer including the light blocking layer and the barrier wall layer on the light blocking layer is formed via a single exposure process, which can simplify the overall process of fabricating the color filter substrates.

It should be understood that all or a part of steps for implementing the above embodiments may be performed by instructions on a respective hardware with a program which may be stored in a media accessible to a computer, such as disk, optical disk, Read-Only Memory (ROM) or Random Access Memory (RAM) and the like. When executed, the program comprises the steps in the embodiment of above method.

In the embodiments of the various methods in the disclosure, the sequence of the respective step can not be used to limit the order of the steps. For those skilled in the art, the change of the steps order falls within the protective scope of the disclosure without paying creative effort.

The embodiment of the invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

What is claimed is:

1. A color filter substrate comprising:
a base substrate; and
a barrier wall black matrix layer on the base substrate, the barrier wall black matrix layer defining subpixel regions and comprising a light blocking layer and a barrier wall layer on the light blocking layer.

2. The color filter substrate of claim 1, further comprising color layers in the subpixel regions.

3. The color filter substrate of claim 1, wherein the barrier wall black matrix layer is formed of a positive photoresist containing black pigment.

4. The color filter substrate of claim 1, wherein the barrier wall layer has a cross-sectional shape selected from the group consisting of trapezium, rectangle and triangle.

5. The color filter substrate of claim 1, wherein the barrier wall layer does not extend beyond the light blocking layer.

6. The color filter substrate of claim 1, wherein the barrier wall layer has a width smaller than a width of the light blocking layer.

7. The color filter substrate of claim 1, wherein the barrier wall layer is continuous to form grids.

8. The color filter substrate of claim 1, wherein the barrier wall layer comprises a plurality of separate portions each located between adjacent subpixel regions.

9. The color filter substrate of claim 1, wherein the barrier wall black matrix layer is formed by a single exposure process.

10. A fabricating method of a color filter substrate, the method comprising steps of:
providing a base substrate;
providing a layer of black matrix material on the base substrate; and
exposing the layer of black matrix material to form a barrier wall black matrix layer defining subpixel regions, the barrier wall black matrix layer comprising a light blocking layer and a barrier wall layer on the light blocking layer.

11. The method of claim 10, wherein the black matrix material is formed of a positive photoresist containing black pigment.

12. The method of claim 11, wherein the step of said exposing the layer of black matrix material comprises steps of:
exposing the photoresist by using a half tone mask or a grey tone mask such that the exposed photoresist comprises a completely exposed region, an unexposed region and a partially exposed region; and
removing the exposed photoresist by a developing process to form a barrier wall layer corresponding to the unexposed regions, a light blocking layer corresponding to the partially exposed regions, and the subpixel regions corresponding to the completely exposed region.

13. The method of claim 10, further comprising a step of dispensing color inks into the subpixel regions by an inkjet method to form a plurality of color layers.

14. The method of claim 13, wherein before said step of dispensing the color inks into the subpixel region, the method further comprises:
thinning the barrier wall layer and the light blocking layer to a predetermined thickness by an ashing process.

15. A liquid crystal display comprising:
a color filter substrate comprising
a base substrate; and
a barrier wall black matrix layer on the base substrate, the barrier wall black matrix layer defining subpixel regions and comprising a light blocking layer and a barrier wall layer on the light blocking layer.

16. The liquid crystal display of claim 15, further comprising color layers in the subpixel regions.

17. The liquid crystal display of claim 15, wherein the barrier wall black matrix layer is formed of a positive photoresist containing black pigment.

18. The liquid crystal display of claim 15, wherein the barrier wall layer does not extend beyond the light blocking layer.

19. The liquid crystal display of claim 15, wherein the barrier wall layer is continuous.

20. The liquid crystal display of claim 15, wherein the barrier wall layer comprises a plurality of separate portions each located between adjacent subpixel regions.
